(19) United States
(12) Patent Application Publication
(10) Pub. No.: US 2010/0308466 A1
(43) Pub. Date: Dec. 9, 2010

(54) SEMICONDUCTOR DEVICE AND METHOD OF MANUFACTURING SEMICONDUCTOR DEVICE

(75) Inventor: Kazuaki TAKESAKO, Tokyo (JP)

Correspondence Address: YOUNG & THOMPSON, 209 Madison Street, Suite 500, Alexandria, VA, 22314, US

(73) Assignee: ELPIDA MEMORY, INC, Tokyo (JP)

(21) Appl. No.: 12/791,548

(22) Filed: Jun. 1, 2010

(30) Foreign Application Priority Data
Jun. 3, 2009 (JP) 2009-134167

(51) Int. Cl. H01L 23/52

(52) U.S. Cl. 257/773; 257/E23.141

(57) ABSTRACT

A semiconductor device includes a substrate; first and second semiconductor pillars; a first insulator; and a first wiring layer. The first and second semiconductor pillars are disposed over the substrate. The first and second semiconductor pillars may be aligned in a first direction. The first insulator may eclectically isolate the first and second semiconductor pillars from each other. The first wiring layer may continuously extend inside a first continuing groove that extends through the first and second semiconductor pillars and the first insulator. The first continuing groove extends in a first direction along which the first and second semiconductor pillars are aligned.

### BACKGROUND OF THE INVENTION

1. Field of the Invention

The present invention relates to a semiconductor device and a method of manufacturing the semiconductor device. More specifically, the present invention relates to a semiconductor device including semiconductor pillars (Si pillars) and a method of manufacturing the semiconductor device.

Priority is claimed on Japanese Patent Application No. 2009-134167, filed Jun. 3, 2009, the content of which is incorporated herein by reference.

2. Description of the Related Art

As semiconductor devices suitable for a high degree of integration and shrinkage, a semiconductor device has been proposed, which includes a transistor with a double gate structure in which gate electrodes are formed so as to interpose a Si pillar, or includes a transistor with a surround gate structure in which the gate electrode is formed so as to surround the Si pillar. These semiconductor devices are disclosed in Japanese Unexamined Patent Application, First Publications, Nos. JP-A-2008-177573, JP-A-2001-298166, JP-A-2006-41513, and JP-A-5-6977.

In general, when a transistor including a Si pillar is formed, a gate electrode that is electrically isolated from the gate electrodes of adjacent transistors is formed as follows. A conductor which will be a gate electrode in a groove that is provided between a plurality of Si pillars arranged at a small pitch and etches back the conductor using the difference in the width of the groove between the Si pillars. The conductor is etched back using a side wall formed in the groove as a mask.

In the transistor, in general, a word line that connects the gate electrodes of the transistors is formed in the groove between the Si pillars.

However, with a reduction in the size of the semiconductor device, it has been difficult to etch back the conductor which will be a gate electrode using the difference in the width of the groove between the Si pillars or form the side wall for isolating the gate electrode in the groove.

In the transistor including the Si pillar, in general, an upper contact serving as a source and a drain needs to be formed on the Si pillar. However, with a reduction in the size of the semiconductor device, it is difficult to sufficiently ensure the area of an upper part of the Si pillar. Specifically, when the area of the upper part of the Si pillar is sufficiently ensured without increasing the pitch between the Si pillars, it is difficult to form the word line in the groove between the Si pillars. Therefore, it is necessary to reduce the area of the upper part of the Si pillar. When the area of the upper contact is insufficient, contact resistance increases.

### SUMMARY

In one embodiment, a semiconductor device may include, but is not limited to, a semiconductor substrate; a first pillar alignment; a first insulating film; and a first wiring layer. The first pillar alignment is disposed over the substrate. The first pillar alignment may include, but is not limited to, first and second semiconductor pillars and a first insulating pillar. The first insulating pillar is disposed between the first and second semiconductor pillars. The first pillar alignment is directed in a first direction. The first pillar alignment has a first side surface having a first groove. The first groove extends in the first direction. The first insulating film covers at least part of an inside wall of the first groove. The first wiring layer is disposed in the first groove. The first wiring layer extends in the first direction. The first wiring layer is separated by the first insulating film from the first and second semiconductor pillars.

In another embodiment, a semiconductor device may include, but is not limited to, a substrate; first and second semiconductor pillars; a first insulating pillar; a first insulating film; and a first wiring layer. The first and second semiconductor pillars are disposed over the substrate. The first and second semiconductor pillars are aligned in a first direction. The first and second semiconductor pillars may have first and second grooves extending in the first direction. The first insulating pillar disposed between the first and second semiconductor pillars. The first insulating pillar may eclectically isolate the first and second semiconductor pillars from each other. The first insulating pillar may have a third groove extending in the first direction. The first, third and second grooves form a first continuing groove extending in the first direction. The first insulating film covers at least the first and second grooves. The first wiring layer extends in the first continuing groove. The first wiring layer extends in the first direction. The first wiring layer is separated by the first insulating film from the first and second semiconductor pillars.

In still another embodiment, a semiconductor device may include, but is not limited to, a substrate; first and second semiconductor pillars; a first insulator; and a first wiring layer. The first and second semiconductor pillars are disposed over the substrate. The first and second semiconductor pillars may be aligned in a first direction. The first insulator may eclectically isolate the first and second semiconductor pillars from each other. The first wiring layer may continuously extend inside a first continuing groove that extends through the first and second semiconductor pillars and the first insulator. The first continuing groove extends in a first direction along which the first and second semiconductor pillars are aligned.

In yet another embodiment, a method of forming a semiconductor device may include, but is not limited to, the following processes. A plurality of pillar alignments is formed over a semiconductor substrate. Each of the plurality of pillar alignments may include, but is not limited to, a plurality of semiconductor pillars and a plurality of insulating pillars. The plurality of semiconductor pillars is aligned in a first direction. The plurality of insulating pillars extends in a second direction perpendicular to the first direction. Two adjacent semiconductor pillars of the plurality of semiconductor pillars are separated by the insulating pillar. The plurality of pillar alignments are separated by a plurality of first grooves. Side walls are formed on each of the plurality of first grooves. A plurality of second grooves is formed which is each continued from the first groove. Each of the plurality of second grooves extends in the first direction and inside the pillar alignment.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a semiconductor device in accordance with a first preferred embodiment of the present invention;

FIG. 2 is a fragmentary perspective view illustrating the semiconductor device of FIG. 1;

FIG. 3 is a cross-sectional elevation view illustrating the semiconductor device, taken along a B-B′ line of FIGS. 1 and 2;

FIG. 4 is a cross-sectional elevation view illustrating the semiconductor device, taken along a C-C′ line of FIGS. 1 and 2;

FIG. 5A is a fragmentary plan view illustrating a semiconductor device in a step involved in a method of forming the semiconductor device shown in FIGS. 1, 2 and 3;

FIG. 5B is a fragmentary plan view illustrating the semiconductor device, taken along an A-A′ line of FIG. 5A;

FIG. 6A is a fragmentary plan view illustrating a semiconductor device in a step, subsequent to the step of FIGS. 5A and 5B, involved in the method of forming the semiconductor device shown in FIGS. 1, 2 and 3;

FIG. 6B is a fragmentary plan view illustrating the semiconductor device, taken along an A-A′ line of FIG. 6A;

FIG. 7A is a fragmentary plan view illustrating a semiconductor device in a step, subsequent to the step of FIGS. 6A and 6B, involved in the method of forming the semiconductor device shown in FIGS. 1, 2 and 3;

FIG. 7B is a fragmentary plan view illustrating the semiconductor device, taken along an A-A′ line of FIG. 7A;

FIG. 8A is a fragmentary plan view illustrating a semiconductor device in a step, subsequent to the step of FIGS. 7A and 7B, involved in the method of forming the semiconductor device shown in FIGS. 1, 2 and 3;

FIG. 8B is a fragmentary plan view illustrating the semiconductor device, taken along an A-A′ line of FIG. 8A;

FIG. 9A is a fragmentary plan view illustrating a semiconductor device in a step, subsequent to the step of FIGS. 8A and 8B, involved in the method of forming the semiconductor device shown in FIGS. 1, 2 and 3;

FIG. 9B is a fragmentary plan view illustrating the semiconductor device, taken along an A-A′ line of FIG. 9A;

FIG. 10A is a fragmentary plan view illustrating a semiconductor device in a step, subsequent to the step of FIGS. 9A and 9B, involved in the method of forming the semiconductor device shown in FIGS. 1, 2 and 3;

FIG. 10B is a fragmentary plan view illustrating the semiconductor device, taken along an A-A′ line of FIG. 10A;

FIG. 11A is a fragmentary plan view illustrating a semiconductor device in a step, subsequent to the step of FIGS. 10A and 10B, involved in the method of forming the semiconductor device shown in FIGS. 1, 2 and 3;

FIG. 11B is a fragmentary plan view illustrating the semiconductor device, taken along an A-A′ line of FIG. 11A;

FIG. 12A is a fragmentary plan view illustrating a semiconductor device in a step, subsequent to the step of FIGS. 11A and 11B, involved in the method of forming the semiconductor device shown in FIGS. 1, 2 and 3;

FIG. 12B is a fragmentary plan view illustrating the semiconductor device, taken along an A-A′ line of FIG. 12A;

FIG. 13A is a fragmentary plan view illustrating a semiconductor device in a step, subsequent to the step of FIGS. 11A and 11B, involved in the method of forming the semiconductor device shown in FIGS. 1, 2 and 3;

FIG. 13B is a fragmentary plan view illustrating the semiconductor device, taken along a B-B′ line of FIG. 13A;

FIG. 13C is a fragmentary plan view illustrating the semiconductor device, taken along a C-C′ line of FIG. 13A;

FIG. 14A is a fragmentary plan view illustrating a semiconductor device in a step, subsequent to the step of FIGS. 13A and 13B, involved in the method of forming the semiconductor device shown in FIGS. 1, 2 and 3;

FIG. 14B is a fragmentary plan view illustrating the semiconductor device, taken along a B-B′ line of FIG. 14A;

FIG. 14C is a fragmentary plan view illustrating the semiconductor device, taken along a C-C′ line of FIG. 14A;

FIG. 15A is a fragmentary plan view illustrating a semiconductor device in a step, subsequent to the step of FIGS. 14A and 14B, involved in the method of forming the semiconductor device shown in FIGS. 1, 2 and 3;

FIG. 15B is a fragmentary plan view illustrating the semiconductor device, taken along a B-B′ line of FIG. 15A;

FIG. 15C is a fragmentary plan view illustrating the semiconductor device, taken along a C-C′ line of FIG. 15A;

FIG. 16A is a fragmentary plan view illustrating a semiconductor device in a step, subsequent to the step of FIGS. 15A and 15B, involved in the method of forming the semiconductor device shown in FIGS. 1, 2 and 3;

FIG. 16B is a fragmentary plan view illustrating the semiconductor device, taken along a B-B′ line of FIG. 16A;

FIG. 16C is a fragmentary plan view illustrating the semiconductor device, taken along a C-C′ line of FIG. 16A;

FIG. 17A is a fragmentary plan view illustrating a semiconductor device in a step, subsequent to the step of FIGS. 16A and 16B, involved in the method of forming the semiconductor device shown in FIGS. 1, 2 and 3;

FIG. 17B is a fragmentary plan view illustrating the semiconductor device, taken along a B-B′ line of FIG. 17A;

FIG. 17C is a fragmentary plan view illustrating the semiconductor device, taken along a C-C′ line of FIG. 17A;

FIG. 18A is a fragmentary plan view illustrating a semiconductor device in a step, subsequent to the step of FIGS. 17A and 17B, involved in the method of fowling the semiconductor device shown in FIGS. 1, 2 and 3;

FIG. 18B is a fragmentary plan view illustrating the semiconductor device, taken along a B-B′ line of FIG. 18A;

FIG. 18C is a fragmentary plan view illustrating the semiconductor device, taken along a C-C′ line of FIG. 18A;

FIG. 19 is a fragmentary plan view illustrating a semiconductor device in accordance with a second preferred embodiment of the present invention;

FIG. 20 is a fragmentary perspective view illustrating the semiconductor device of FIG. 19;

FIG. 21 is a cross-sectional elevation view illustrating the semiconductor device, taken along a C-C′ line of FIGS. 19 and 20; and

FIG. 22 is a fragmentary plan view illustrating a semiconductor device in a step involved in a method of forming the semiconductor device shown in FIGS. 19 and 20.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a semiconductor device may include, but is not limited to, a semiconductor substrate; a first pillar alignment; a first insulating film; and a first wiring layer. The first pillar alignment is disposed over the substrate. The first pillar alignment may include, but is not limited to, first and second semiconductor pillars and a first insulating pillar. The first insulating pillar is disposed between the first and second semiconductor pillars. The first pillar alignment is directed in a first direction. The first pillar alignment has a first side surface having a first groove. The first groove extends in the first direction. The first insulating film covers at least part of an inside wall of the first groove. The first wiring layer is disposed in the first groove. The first wiring layer extends in the first direction. The first wiring layer is separated by the first insulating film from the first and second semiconductor pillars.

In some cases, the first pillar alignment may have a second side surface having a second groove. The second groove extends in the first direction. The second side surface is opposite to the first side surface. The semiconductor device may further include, but is not limited to, a second insulating film and a second wiring layer. The second insulating film covers at least part of an inside wall of the second groove. The second wiring layer is disposed in the second groove. The second wiring layer extends in the first direction. The second wiring layer is separated by the second insulating film from the first and second semiconductor pillars.

In some cases, the first and second grooves are separated by each of the first and second semiconductor pillars. The first and second grooves are connected with each other at the first insulating pillar. The first and second wiring layers surround each of the first and second semiconductor pillars.

In some cases, the semiconductor device may further include, but is not limited to, a second pillar alignment, a third insulating film, and a third wiring layer. The second pillar alignment is disposed over the substrate. The second pillar alignment is distanced from the first pillar alignment in a second direction perpendicular to the first direction. The second pillar alignment may include, but is not limited to, third and fourth semiconductor pillars and a second insulating pillar. The second insulating pillar is disposed between the third and fourth semiconductor pillars. The second pillar alignment is directed in the first direction. The second pillar alignment has a third side surface having a third groove. The second groove extends in the first direction. The third insulating film covers at least part of an inside wall of the third groove. The third wiring layer is disposed in the third groove. The third wiring layer extends in the first direction. The third wiring layer is separated by the third insulating film from the third and fourth semiconductor pillars. In some cases, the first, second, third and fourth semiconductor pillars may be arranged in matrix.

In some cases, the second pillar alignment may have a fourth side surface having a fourth groove. The fourth groove extends in the first direction. The fourth side surface is opposite to the third side surface. The semiconductor device may further include, but is not limited to, a fourth insulating film covering at least part of an inside wall of the fourth groove; and a fourth wiring layer in the fourth groove. The fourth wiring layer extends in the first direction. The fourth wiring layer is separated by the fourth insulating film from the third and fourth semiconductor pillars.

In some cases, the third and fourth grooves may be separated by each of the third and fourth semiconductor pillars. The third and fourth grooves may be connected with each other at the second insulating pillar. The third and fourth wiring layers may surround each of the third and fourth semiconductor pillars.

In some cases, the semiconductor substrate may have a fifth groove. The fifth groove may be positioned under the first insulating pillar between the first and second semiconductor pillars. The fifth groove may extend in a second direction parallel to the surface of the semiconductor substrate. The second direction is perpendicular to the first direction. The fifth groove has side walls which have sixth and seventh grooves. The sixth and seventh grooves extend in the second direction. The semiconductor device may further include, but is not limited to, fifth and sixth wiring layers in the sixth and seventh grooves, respectively. The fifth and sixth wiring layers extend in the second direction.

In some cases, the sixth and seventh grooves may be positioned at lower portions of the side walls of the fifth groove.

In some cases, the fifth groove may be filled with an insulating material.

In some cases, the fifth and sixth wiring layers may be bit lines. The first wiring layer may be a word line.

In some cases, the first side surface of the first pillar alignment may be a continuing flat side surface. The first groove may continuously extend in the first direction.

In some cases, the first groove may be positioned at a lower portion of the first pillar alignment.

In another embodiment, a semiconductor device may include, but is not limited to, a substrate; first and second semiconductor pillars; a first insulating pillar; a first insulating film; and a first wiring layer. The first and second semiconductor pillars are disposed over the substrate. The first and second semiconductor pillars are aligned in a first direction. The first and second semiconductor pillars may have first and second grooves extending in the first direction. The first insulating pillar disposed between the first and second semiconductor pillars. The first insulating pillar may eclectically isolate the first and second semiconductor pillars from each other. The first insulating pillar may have a third groove extending in the first direction. The first, third and second grooves form a first continuing groove extending in the first direction. The first insulating film covers at least the first and second grooves. The first wiring layer extends in the first continuing groove. The first wiring layer extends in the first direction. The first wiring layer is separated by the first insulating film from the first and second semiconductor pillars.

In some cases, the first and second semiconductor pillars may have fourth and fifth grooves extending in the first direction. The fourth and fifth grooves may be positioned in opposite side to the first and second grooves. The first insulating pillar may have a sixth groove extending in the first direction. The fourth, sixth and fifth grooves may form a second continuing groove extending in the first direction. The second insulating film may cover at least the fourth and fifth grooves. The second wiring layer may extend in the second continuing groove. The second wiring layer may extend in the first direction. The second wiring layer is separated by the second insulating film from the first and second semiconductor pillars.

In some cases, the semiconductor device may further include third and fourth semiconductor pillars, a second insulating pillar, a third insulating film, and a third wiring layer. The third and fourth semiconductor pillars may be disposed over the substrate. The third and fourth semiconductor pillars may be aligned in the first direction. The third and fourth semiconductor pillars may be distanced from the first and second semiconductor pillars. The third and fourth semiconductor pillars may have seventh and eighth grooves extending in the first direction. The second insulating pillar may be disposed between the third and fourth semiconductor pillars. The second insulating pillar may eclectically isolate the third and fourth semiconductor pillars from each other. The second insulating pillar may have a ninth groove extending in the first direction. The seventh, ninth and eighth grooves forms a third continuing groove extending in the first direction. The third insulating film covers at least the seventh and eighth grooves. The third wiring layer extends in the third continuing groove. The third wiring layer extends in the first direction. The third wiring layer may be separated by the third insulating film from the third and fourth semiconductor pillars.

In still another embodiment, a semiconductor device may include, but is not limited to, a substrate; first and second semiconductor pillars; a first insulator; and a first wiring layer. The first and second semiconductor pillars are disposed over the substrate. The first and second semiconductor pillars may be aligned in a first direction. The first insulator may eclectically isolate the first and second semiconductor pillars from each other. The first wiring layer may continuously extend inside a first continuing groove that extends through the first and second semiconductor pillars and the first insulator. The first continuing groove extends in a first direction along which the first and second semiconductor pillars are aligned.

In some cases, the semiconductor substrate may have a second continuing groove that extends in a second direction perpendicular to the first direction. The second continuing groove may be positioned under the first insulator between the first and second semiconductor pillars. The second continuing groove may have side walls which have third and fourth grooves. The third and fourth grooves may extend in the second direction. The semiconductor device may further include, but is not limited to, second and third wiring layers in the third and fourth grooves, respectively. The second and third wiring layers extend in the second direction.

In some cases, the first wiring layer may be a word line. The second and third wiring layers may be bit lines.

In still another embodiment, a method of forming a semiconductor device may include, but is not limited to, the following processes. A plurality of pillar alignments is formed over a semiconductor substrate. Each of the plurality of pillar alignments may include, but is not limited to, a plurality of semiconductor pillars and a plurality of insulating pillars. The plurality of semiconductor pillars is aligned in a first direction. The plurality of insulating pillars extends in a second direction perpendicular to the first direction. Two adjacent semiconductor pillars of the plurality of semiconductor pillars are separated by the insulating pillar. The plurality of pillar alignments are separated by a plurality of first grooves. Side walls are formed on each of the plurality of first grooves. A plurality of second grooves is formed which is each continued from the first groove. Each of the plurality of second grooves extends in the first direction and inside the pillar alignment.

In some cases, the method may further include, but is not limited to, the following processes. The side walls are removed from the plurality of first grooves. First insulating films are formed on inside walls of the second grooves. First wiring layers are formed on the first insulating films. The first wiring layers may be inside the second grooves.

In some cases, the first wiring layers may be formed by filling the second grooves with a first conductive material; and partially removing the first conductive material to leave the first conductive material only inside the second grooves.

In some cases, the plurality of second grooves may be formed by isotropically etching the bottom of each of the plurality of first grooves to form the second grooves in opposite sides of each of the plurality of pillar alignments.

In some cases, the bottom of each of the plurality of first grooves may be etched by isotropically etching the semiconductor pillars and the plurality of insulating pillars at the same etching rate.

In some cases, the bottom of each of the plurality of first grooves may be isotropically etched by forming the plurality of second grooves which penetrate the insulating pillars and not penetrate the semiconductor pillars, so that each of the semiconductor pillars is surrounded by the plurality of second grooves.

In some cases, the plurality of pillar alignments separated by the plurality of first grooves may be formed by forming a plurality of isolation grooves in the semiconductor substrate, the plurality of isolation grooves extending in the second direction; forming a second insulating film in each of the plurality of isolation grooves; and etching the semiconductor substrate and the second insulating films at the same etching rate.

In some cases, the method may further include, but is not limited to, the following processes. Side walls are formed on the side surfaces of the plurality of isolation grooves. The bottoms of the plurality of isolation grooves may be formed by using the side walls as masks to form third grooves in the side walls of the plurality of isolation grooves. The third grooves extend in the second direction. The side walls may be removed. Second wiring layers are formed inside the third grooves.

In some cases, the second wiring layers may be formed by filling the third grooves with a second conductive material; and partially removing the second conductive material to leave the second conductive material only inside the third grooves.

### First Embodiment

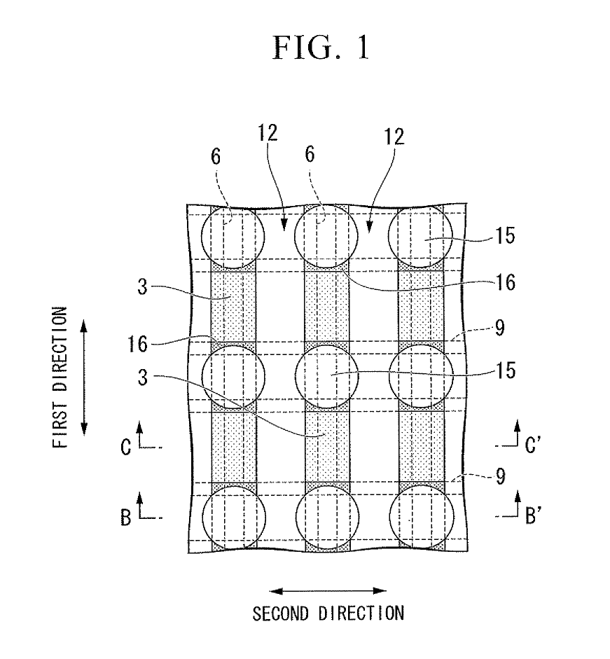

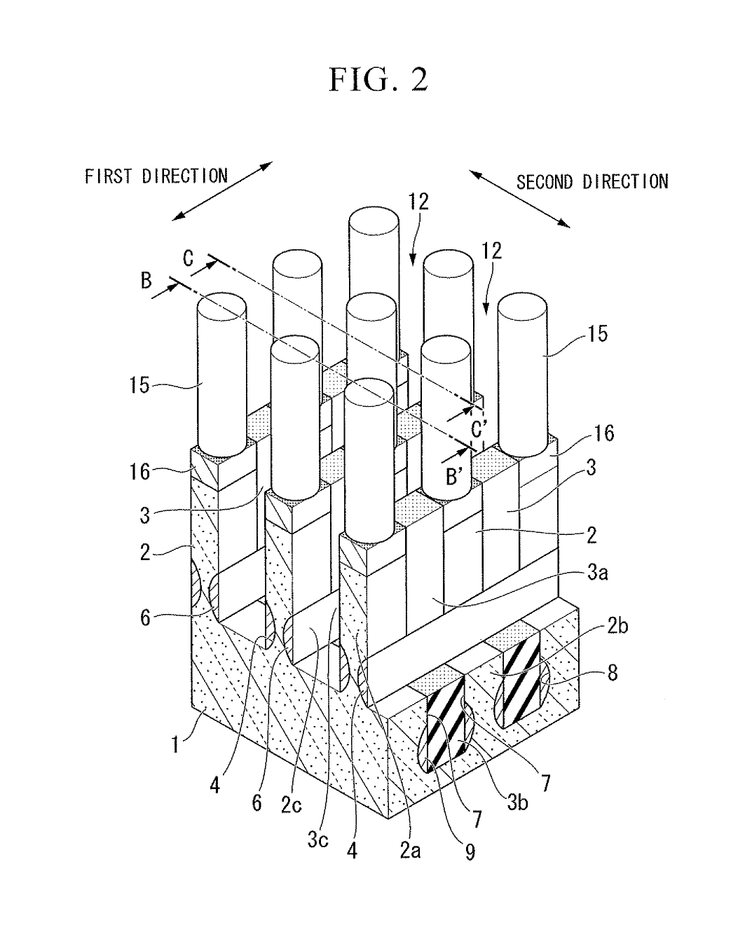

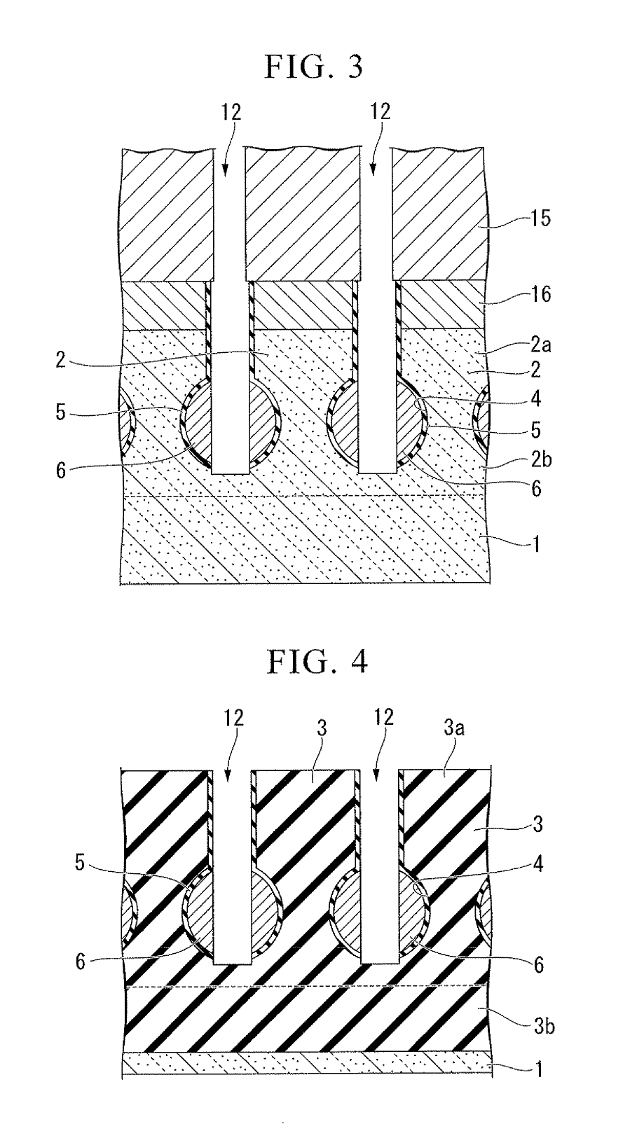

FIG. 1 is a plan view schematically illustrating the planar structure of a DRAM as a semiconductor device in a step involved in a manufacturing process, according to an embodiment of the present invention. FIG. 2 is a perspective view illustrating the DRAM shown in FIG. 1. FIG. 3 is a cross-sectional elevation view illustrating the DRAM shown in FIGS. 1 and 2 taken along the line B-B′ of FIGS. 1 and 2. FIG. 4 is a cross-sectional view illustrating the DRAM shown in FIGS. 1 and 2 taken along the line C-C′ of FIGS. 1 and 2.

The DRAM according to this embodiment shown in FIGS. 1 to 4 includes a plurality of semiconductor pillars 2 that is arranged in a matrix over a silicon substrate 1, which is a semiconductor substrate, in a first direction in which gate lines (wiring layers) 6 extend and a second direction which intersects the first direction and in which bit lines 9 (conductive lines) extend. In the DRAM according to this embodiment, the gate lines 6 are formed so as to extend to a peripheral circuit. The gate lines 6 also serve as word lines. As shown in FIGS. 1 and 2, the semiconductor pillar 2 is a pillar having a rectangular shape in a plan view in which one side portion that extends in the first direction and has an effect on the gap between the bit lines 9 which are provided at a position lower than the gate lines 6 from the surface is longer than another side portion extending in the second direction. In this embodiment, the semiconductor pillar 2 has a rectangular shape in a plan view in which one side portion extending in the first direction is longer than another side portion extending in the second direction. The semiconductor pillar 2 may have a rectangular shape in a plan view in which one side portion extending in the second direction is longer than another side portion extending in the first direction. In other cases, the semiconductor pillar 2 may have a square shape or a parallelogram shape in a plan view. In the DRAM according to this embodiment, the second direction is orthogonal to the first direction. However, the second direction may not be orthogonal to the first direction as long as it intersects the first direction.

As shown in FIG. 3, an upper contact 16 and a cylinder 15 are formed in this order over the semiconductor pillar 2.

As shown in FIGS. 2 and 3, the semiconductor pillars 2 are formed by patterning the silicon substrate 1. The semiconductor pillars 2 may each have a columnar portion 2a. The columnar portion 2a of the semiconductor pillar 2 includes a base portion 2b that has a linear shape in a plan view and extends in the second direction perpendicular to the first direction at a predetermined depth. The base portions 2b of the semiconductor pillars 2 are formed by patterning the silicon substrate 1 and are separated from each other by an isolation groove 7 that is provided between the base portions 2b of the semiconductor pillars 2 adjacent to each other in the first direction and extends in the second direction.

As shown in FIG. 2, a bit line groove 8 as a second wiring groove is continuously provided on the side wall of the isolation groove 7 in the second direction. The bit line groove 8 has an arc shape in a cross-sectional view. The bit line groove 8 is provided on the entire side wall of the isolation groove 7 in the second direction. The bit line 9 is buried in the bit line groove 8. As shown in FIG. 2, the bit lines 9 are provided so that the base portion 2b of the semiconductor pillar 2 is interposed between the bit lines 9.

As shown in FIGS. 1, 2, and 4, the DRAM according to this embodiment includes insulator pillars 3 that are arranged in a matrix in the first direction and the second direction. As shown in FIGS. 2 and 4, the insulator pillar 3 includes a columnar portion 3a that has the same shape as the columnar portion 2a of each semiconductor pillar 2 and is provided in the first direction between the semiconductor pillars 2 on the silicon substrate 1. In this embodiment, the columnar portion 3a of the insulator pillar 3 has the same shape as the columnar portion 2a of the semiconductor pillar 2, but the shape of the columnar portion 3a may be different from that of the columnar portion 2a of the semiconductor pillar 2. For example, the columnar portion 3a may have a shape in which the length thereof in the first direction is different from that of the semiconductor pillar 2 in a plan view. The insulator pillar 3 includes a base portion 3b that is buried in the silicon substrate 1 at a predetermined depth and extends in the second direction perpendicular to the first direction. As shown in FIGS. 1 and 2, the base portion 3b of the insulator pillar 3 is provided in the isolation groove 7.

As shown in FIG. 2, in the DRAM according to this embodiment, gate grooves (first wiring grooves) 4 are continuously provided in a side wall 2c of the semiconductor pillar 2 and a side wall 3c of the insulator pillar 3 in the first direction. As shown in FIG. 2, the gate grooves 4 have an arc shape in a cross-sectional view that is opened to the groove portions 12 which separate the semiconductor pillars 2 and the insulator pillars 3 in the first direction and are provided in all side walls of the semiconductor pillars 2 and the insulator pillars 3 in the first direction.

As shown in FIGS. 3 and 4, a gate insulating film as a first insulating film 5 not shown in FIG. 2 is provided on the inner wall of the gate groove 4, and a gate line 6 is buried in the gate groove 4. In the DRAM according to this embodiment, as shown in FIGS. 2 and 3, the gate lines 6 are arranged so that the semiconductor pillar 2 with the gate insulating films 5 is interposed between the gate lines 6. A portion of the semiconductor pillar 2 is interposed between the gate lines 6. This portion serves as a channel of the transistor. Therefore, the DRAM according to this embodiment includes a transistor with a vertical double gate structure.

In the DRAM according to this embodiment, as shown in FIGS. 1 and 2, the gate lines 6 adjacent to each other in the second direction are separated by the groove portion 12 extending in the first direction. As shown in FIG. 1, the gate lines 6 and the bit lines 9 are arranged so as to intersect each other in a plan view. As shown in FIG. 2, the gate line 6 is provided at a position lower than the bit line 9 from the surface, and the gate line 6 and the bit line 9 are insulated from each other by the base portion 3b of the insulator pillar 3 at a position where the gate line and the bit line intersect each other in a plan view.

In the DRAM according to this embodiment, as shown in FIGS. 1 to 4, portions of the semiconductor pillar 2 and the insulator pillar 3 and the gate line 6 overlap each other in a plan view, and a portion of the semiconductor pillar 2 and the bit line 9 overlap each other in a plan view.

### Manufacturing Method:

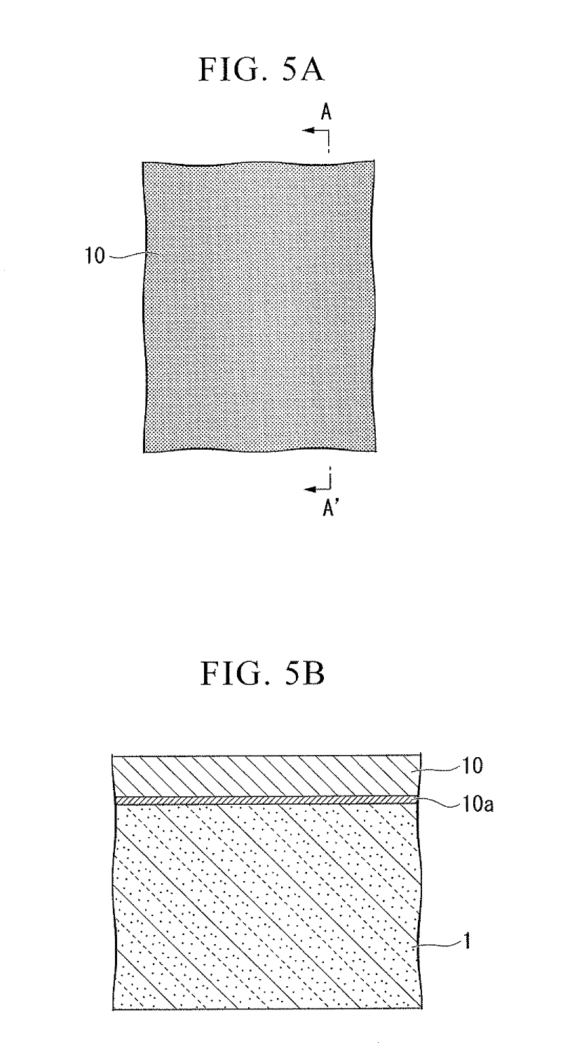

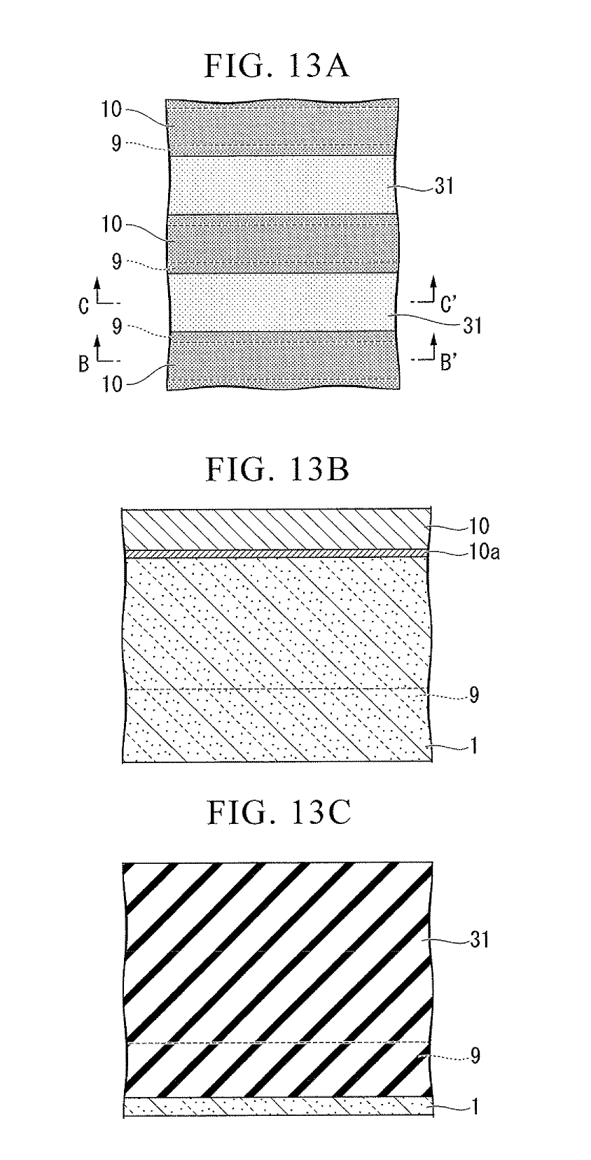

A method of manufacturing the DRAM shown in FIGS. 1 to 4 will be described. FIGS. 5A through 18C are views illustrating a method of manufacturing the DRAM shown in FIGS. 1 to 4. FIGS. 5A, 6A, 7A, 8A, 9A, 10A, 11A, 12A, 13A, 14A, 15A, 16A, 17A, and 18A are plan views of the semiconductor devices involved in the method of forming the semiconductor device. FIGS. 5B, 6B, 7B, 8B, 9B, 10B, 11B, and 12B are cross-sectional views taken along the line A-A′ of FIGS. 5A, 6A, 7A, 8A, 9A, 10A, 11A, and 12A, respectively. FIGS. 13B, 14B, 15B, 16B, 17B, and 18B are cross-sectional views taken along the line B-B′ of FIGS. 13A, 14A, 15A, 16A, 17A, and 18A, respectively. FIGS. 13C, 14C, 15C, 16C, 17C, and 18C are cross-sectional views taken along the line C-C′ of FIGS. 13A, 14A, 15A, 16A, 17A, and 18A, respectively.

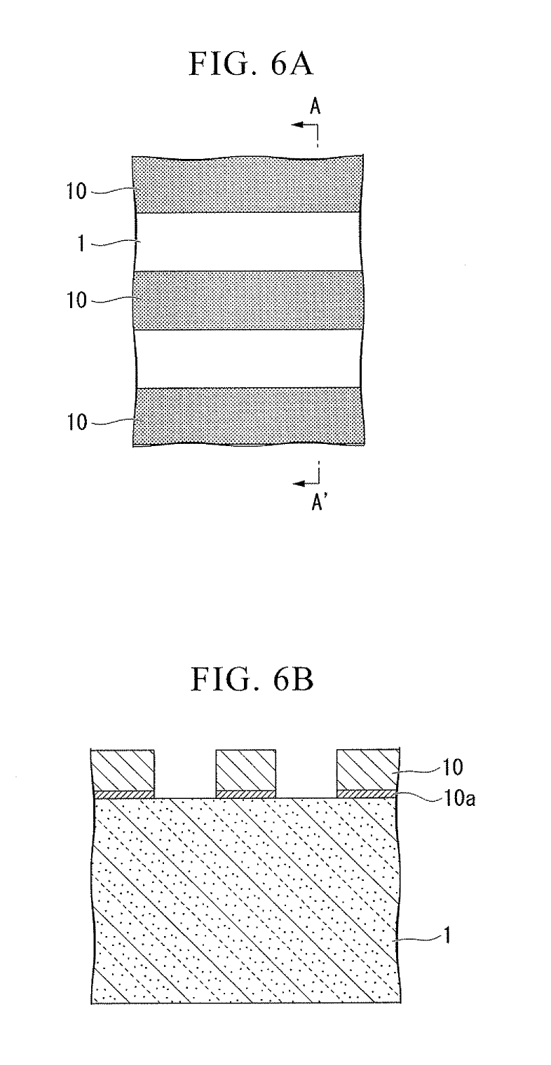

In the method of manufacturing the DRAM shown in FIGS. 1 to 4, an oxide film 10a is provided on the silicon substrate 1. Then, as shown in FIGS. 5A and 5B, a hard mask 10, which is, for example, a nitride film, is provided on the oxide film 10a. As shown in FIGS. 6A and 6B, regions of the oxide film 10a and the hard mask 10 in which the isolation grooves 7 shown in FIG. 2 will be formed are selectively removed and the silicon substrate 1 is exposed.

In this embodiment, the oxide film 10a is provided on the silicon substrate 1. However, the oxide film 10a may not be provided.

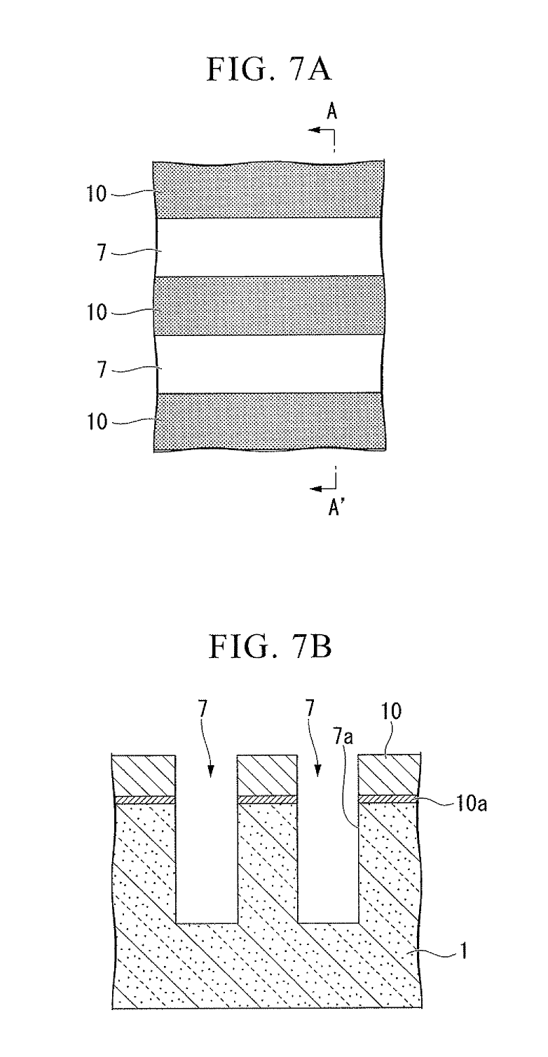

Then, the exposed silicon substrate 1 is etched to form a plurality of isolation grooves 7 in the silicon substrate 1 in the second direction, as shown in FIGS. 7A and 7B (isolation groove forming process).

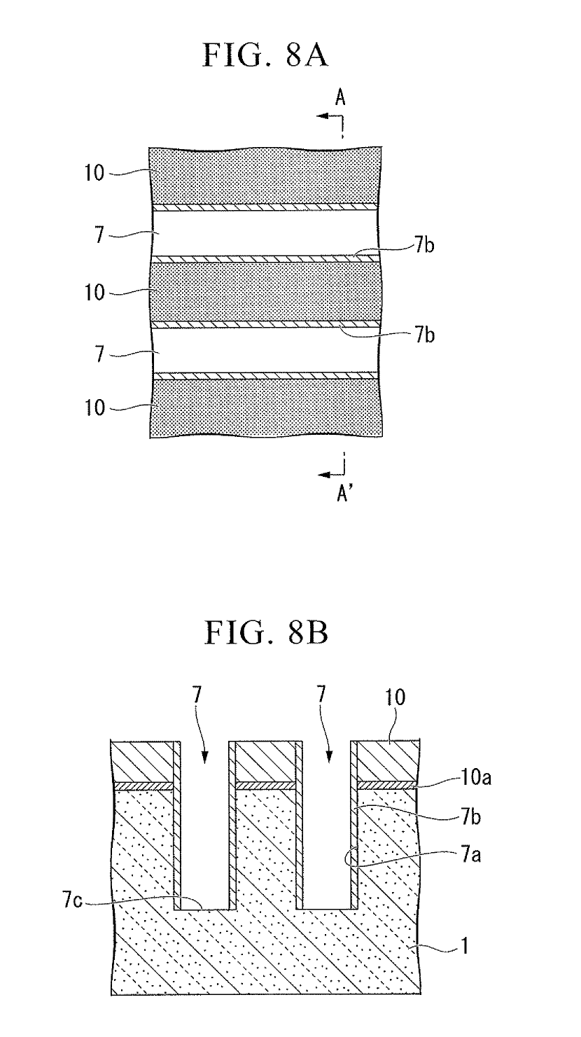

After the isolation groove forming process, as shown in FIGS. 8A and 8B, side walls 7b are formed on the side walls 7a of the isolation grooves 7 and the side walls of the oxide film 10a and the hard mask 10. It is preferable that a film with a sufficiently high etching selectivity (etching rate ratio) with the silicon substrate 1 forming the bottoms 7c of the isolation grooves 7 when wet etching or dry etching is performed on the bottoms 7c of the isolation grooves 7 be used as the side wall 7b. For example, it is preferable to use an oxide film or a nitride film as the side wall 7b.

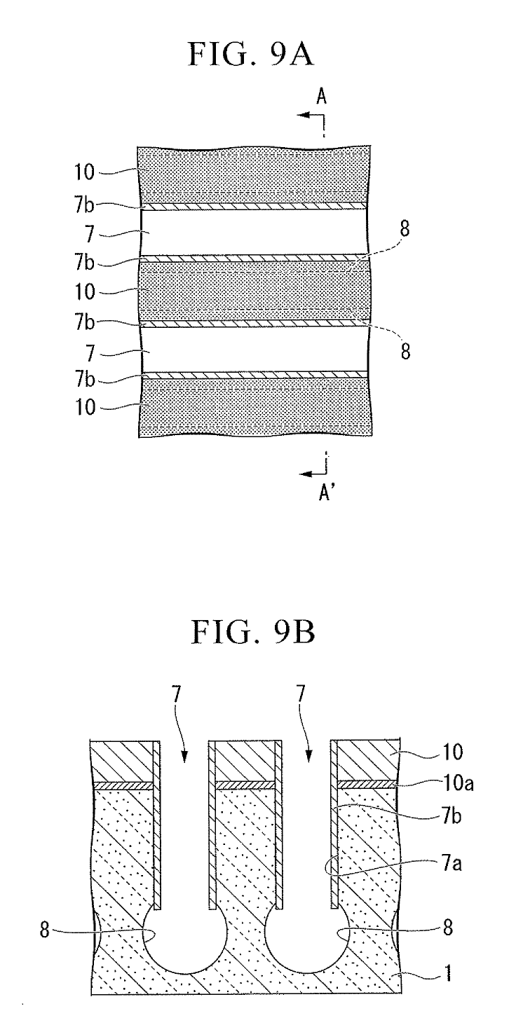

Then, isotropic etching is performed on the bottoms 7c of the isolation grooves 7 shown in FIGS. 8A and 8B using the side wall 7b as a mask. In this way, as shown in FIGS. 9A and 9B, the bit line groove 8 is continuously formed in the side wall 7a of the isolation groove 7 in the second direction. In this case, the etching may be wet etching or dry etching.

The side wall 7b provided when the bottom 7c of the isolation groove 7 is etched is thinner than the side wall that is provided between the semiconductor pillars in order to isolate, for example, a gate electrode. Specifically, the side wall for isolating the gate electrode is generally provided with a thickness equal to or more than that of the gate electrode on the side wall in order to sufficiently ensure the thickness of the gate electrode. In contrast, preferably, the side wall 7b provided when the bottom 7c of the isolation groove 7 is etched is formed with a thickness sufficient to prevent the side wall 7a of the isolation groove 7 from being etched. Therefore, it is possible to reduce the thickness of the side wall 7b provided when the bottom 7c of the isolation groove 7 is etched, as compared to the side wall that is provided in order to isolate the gate electrode. In this embodiment, the side wall 7b is used to etch the bottom 7c of the isolation groove 7. It is not necessary to increase the width of the isolation groove 7 in order to use the side wall 7b.

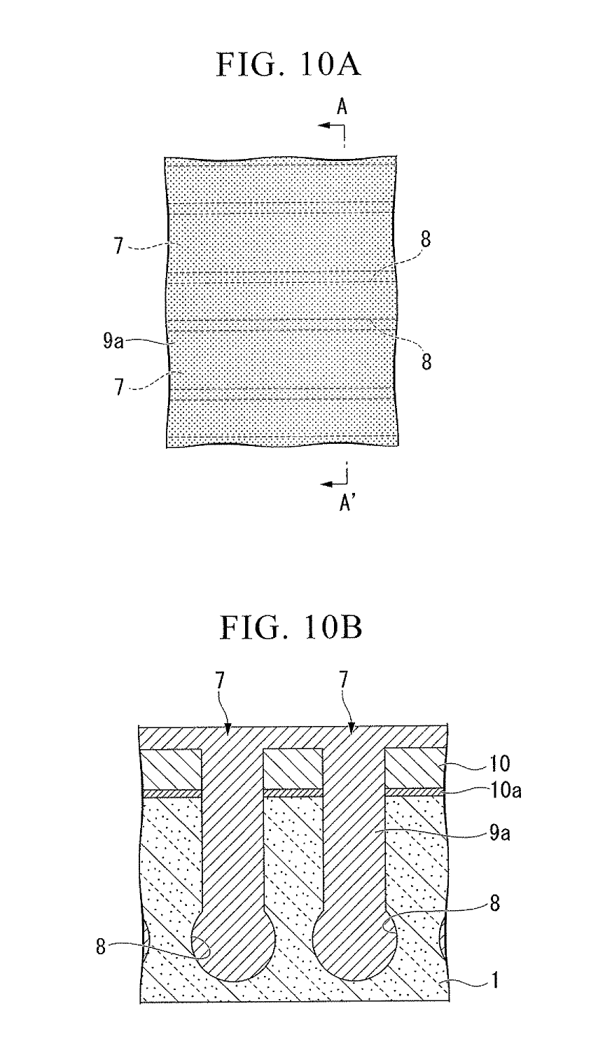

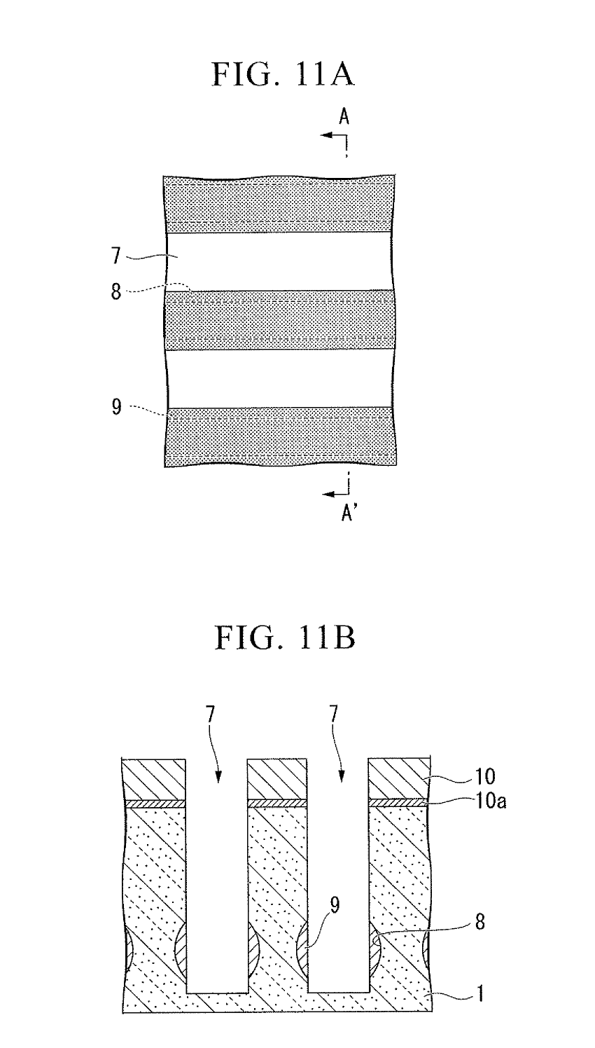

Then, the side wall 7b is removed, and the bit line 9 is provided in the bit line groove 8 (conductive line forming process). In the conductive line forming process, as shown in FIGS. 10A and 10B, a conductor 9a which will be the bit line 9 is provided in the isolation groove 7. Then, a portion of the conductor 9a is selectively removed by dry etching such that the conductor 9a remains only in the bit line groove 8, thereby forming the bit line 9, as shown in FIGS. 11A and 11B.

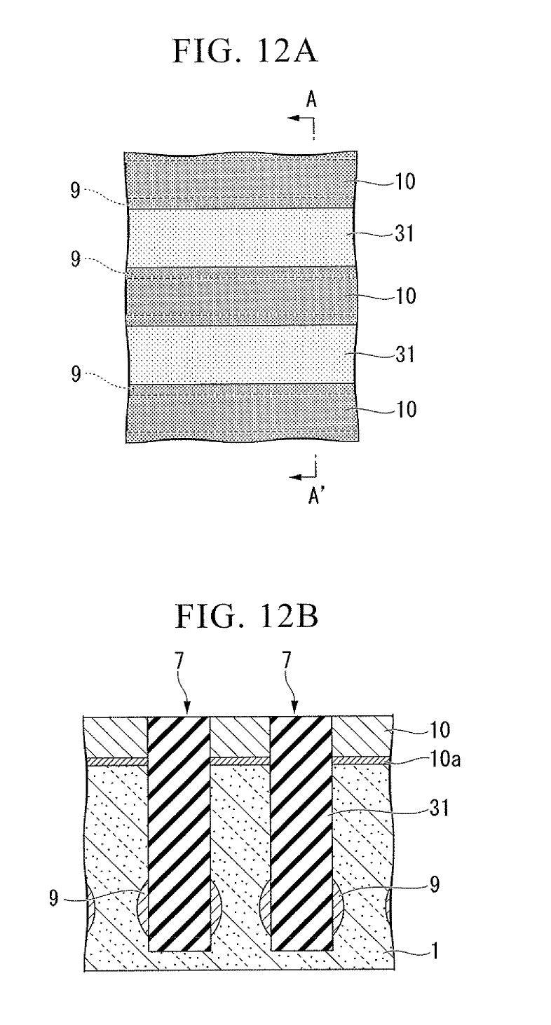

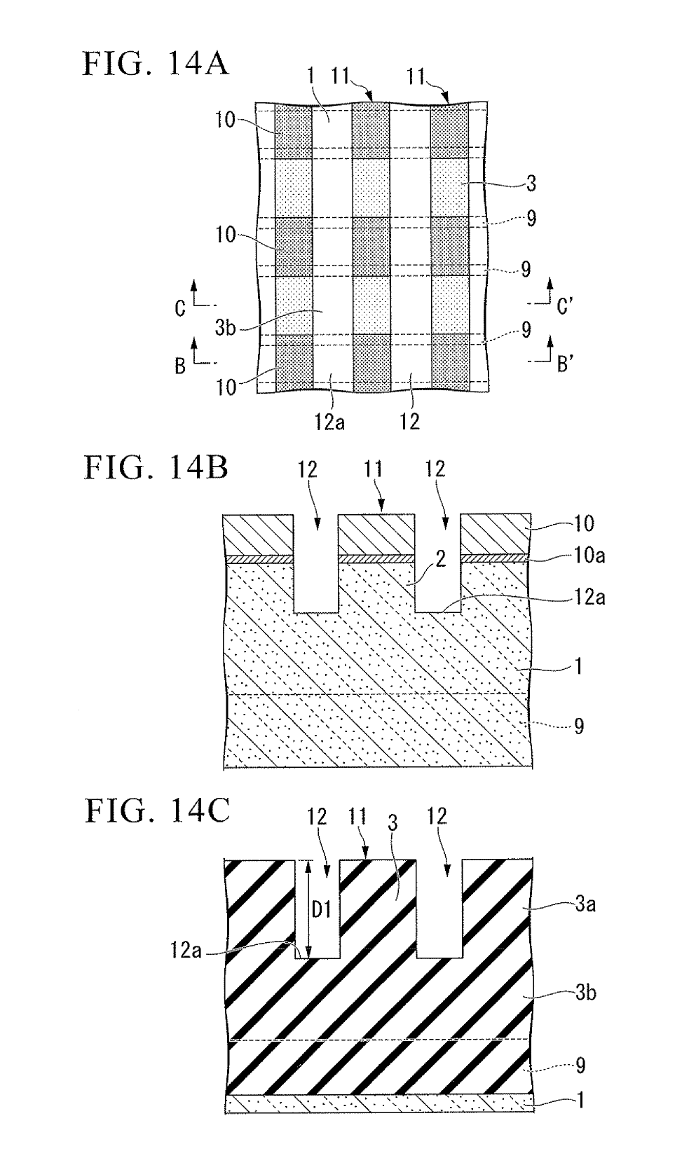

Then, as shown in FIGS. 12A and 12B and FIGS. 13A to 13C, the isolation groove 7 is filled with a second insulating film 31. Then, regions of the oxide film 10a and the hard mask 10 that form the groove portions 12 shown in FIG. 2 are selectively removed, and the exposed silicon substrate 1 and the second insulating film 31 are etched at a constant etching rate, thereby forming pillar columns 11 and the groove portions 12, as shown in FIGS. 14A to 14C (columnar portion forming process).

After the columnar portion forming process ends, as shown in FIGS. 14A to 14C, a plurality of semiconductor pillars 2 and the insulator pillars 3 each having the columnar portion 3a that is provided between the semiconductor pillars 2 on the silicon substrate 1 in the first direction and the base portion 3b that is provided in the silicon substrate 1 at a predetermined depth and extends in the second direction perpendicular to the first direction are formed on the silicon substrate 1. In this way, a plurality of pillar columns 11 each of which includes the semiconductor pillars 2 and the insulator pillars 3 and extends in the first direction and the groove portions 12 that are provided between the plurality of pillar columns 11 and include bottoms 12a through which the silicon substrate 1 and the base portions 3b of the insulator pillars 3 are exposed are formed. In the stage in which the gate lines 6 are formed, the depth D1 of the groove portion 12 is set to a value capable of ensuring a sufficient distance between the gate line 6 and the bit line 9 in the depth direction.

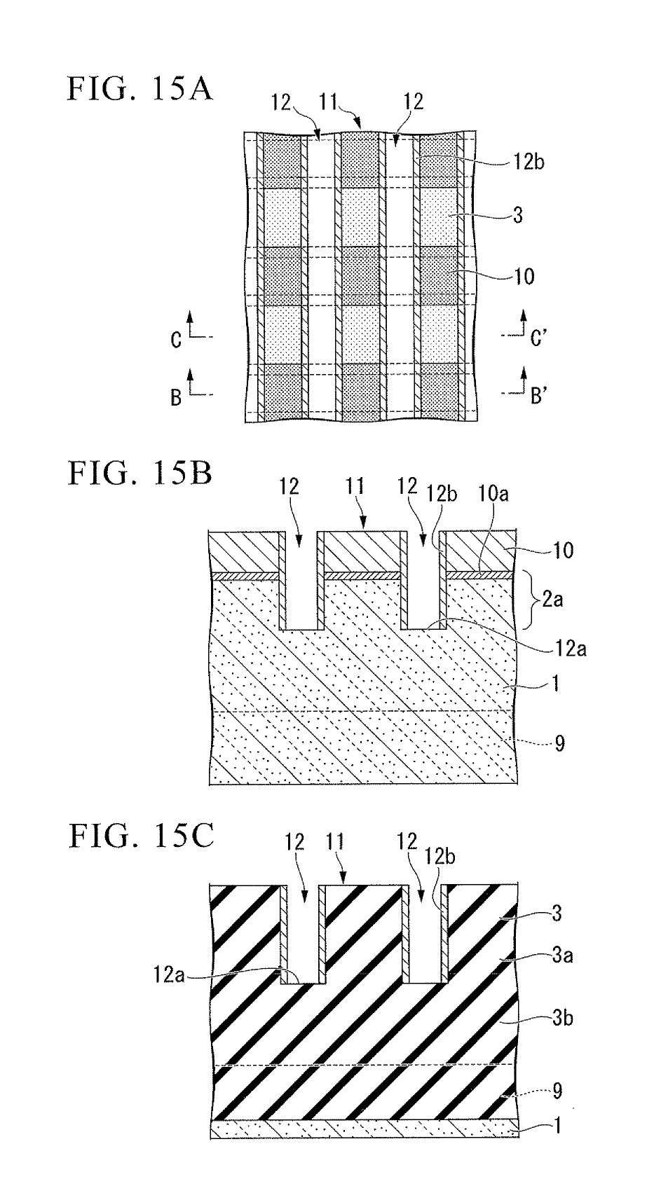

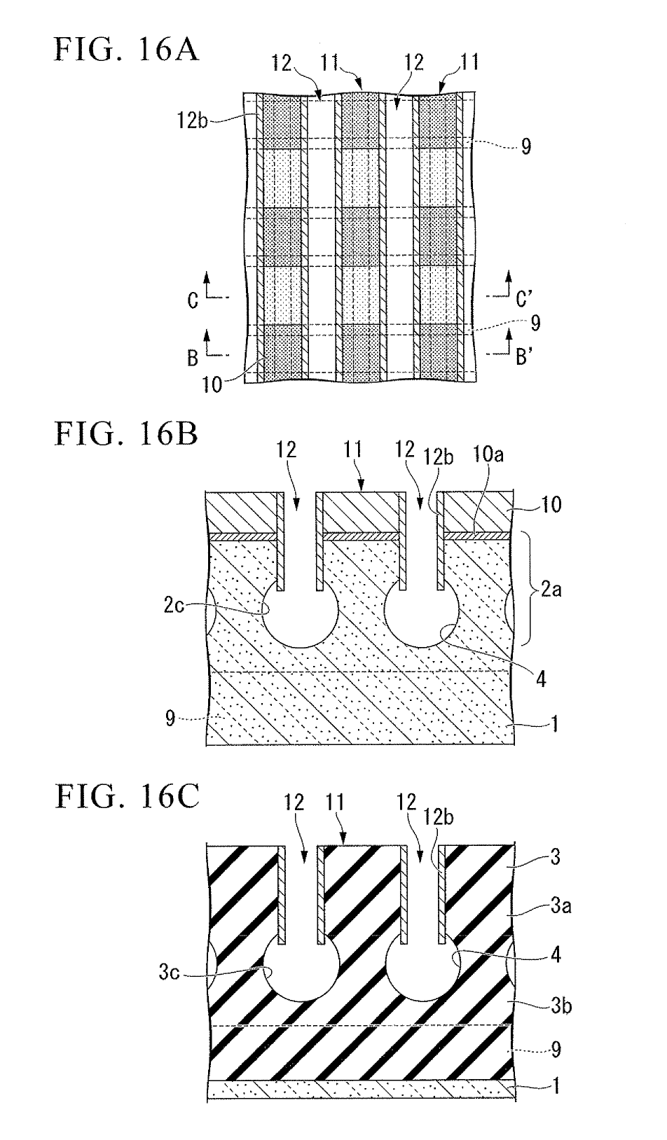

Then, as shown in FIGS. 15A to 15C, a side wall 12b is formed on the side wall of the groove portion 12. Then, isotropic etching is performed on the bottom 12a of the groove portion 12 using the side wall 12b as a mask. In this way, as shown in FIGS. 16A to 16C, the gate groove 4 is continuously formed in the side wall 2c of the semiconductor pillar 2 and the side wall 3c of the insulator pillar 3, and the depth of the groove portion 12 increases. Therefore, the lengths of the semiconductor pillar 2 and the insulator pillar 3 increase (etching process).

In this embodiment, as shown in FIGS. 16A and 16B, in the etching process, the gate grooves 4 are formed in the entire side walls of the pillar columns 11 in the first direction such that the gate grooves 4 are interposed between the semiconductor pillars 2.

In this embodiment, in the etching process, it is preferable that isotropic etching be performed on the silicon substrate 1 and the insulator pillar 3 at a constant etching rate. When the silicon substrate 1 and the insulator pillars 3 are etched at a constant etching rate, it is possible to make the width of the gate groove 4 of the semiconductor pillar 2 equal to that of the gate groove 4 of the insulator pillar 3.

Preferably, the side wall 12b provided when the bottom 12a of the groove portion 12 is etched has a sufficient thickness to prevent the side wall 2c of the semiconductor pillar 2 and the side wall 3c of the insulator pillar 3 from being etched. Therefore, similar to the side wall 7b provided when the bottom 7c of the isolation groove 7 is etched, it is possible to reduce the thickness of the side wall 12b, as compared to the side wall that is provided between the semiconductor pillars in order to isolate the gate electrode. In this embodiment, the side wall 12b is used to etch the bottom 12a of the groove portion 12. It is not necessary to increase the width of the groove portion 12 in order to use the side wall 12b.

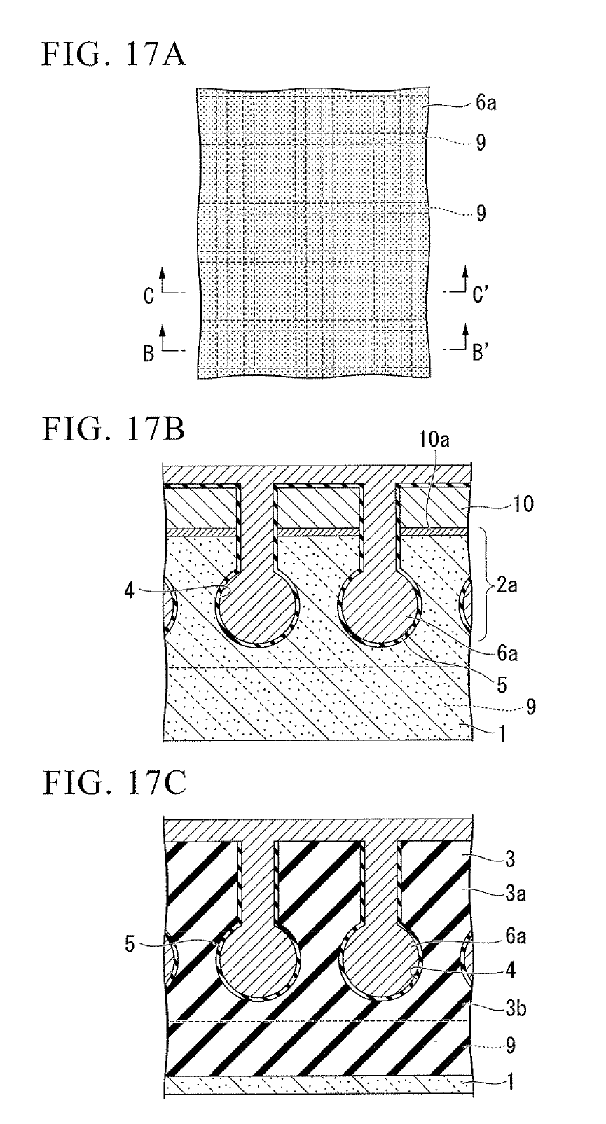

Then, the side wall 12b is removed. A gate insulating film 5 is formed on the inner walls of the gate grooves 4 of the semiconductor pillar 2 and the insulator pillar 3, as shown in FIGS. 17A to 17C. Then, the gate line 6 is provided in the gate groove 4 in the gate line (wiring layer) forming process.

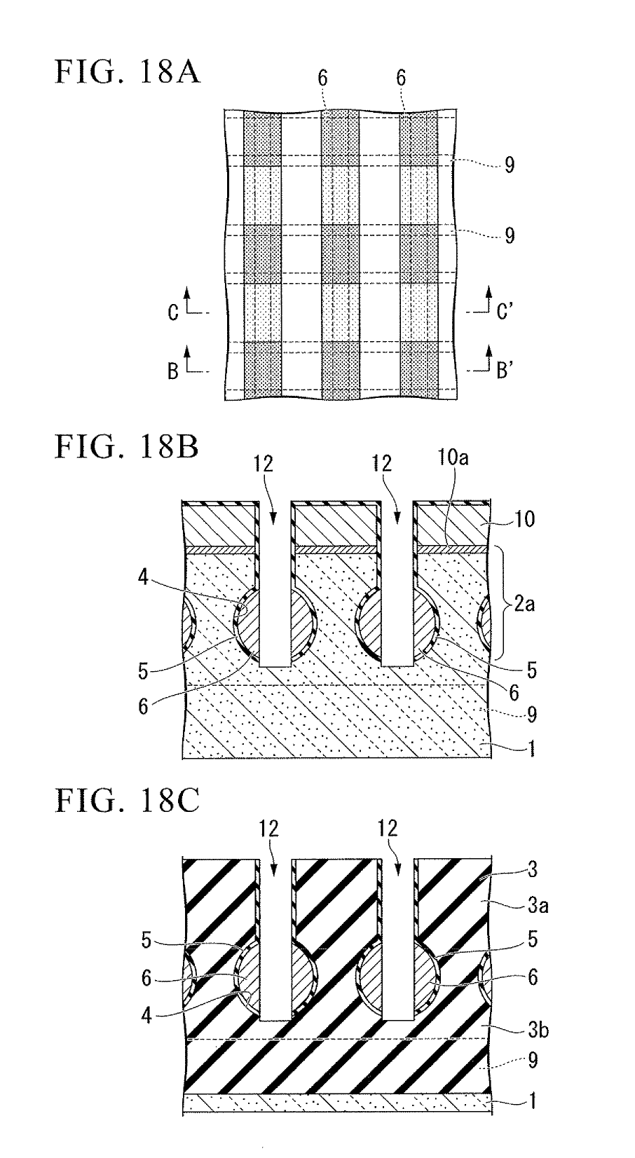

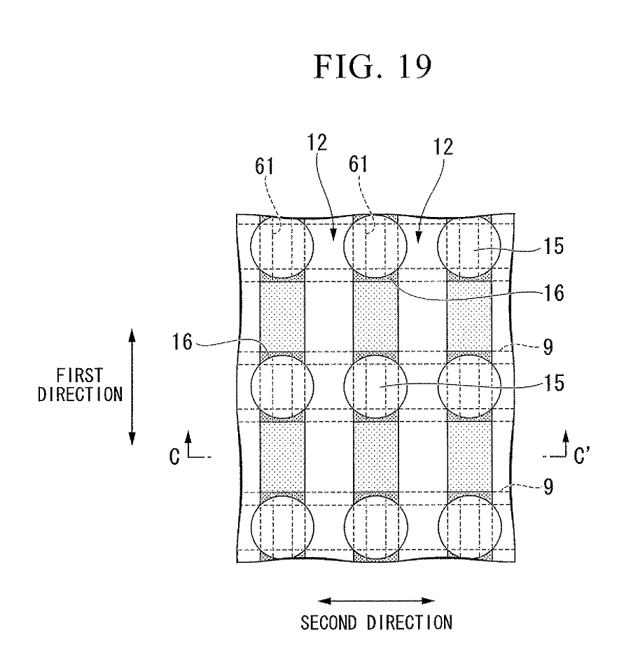

In the gate line forming process, as shown in FIGS. 17A to 17C, a conductor 6a which will be the gate line 6 is provided in the groove portion 12. Then, a portion of the conductor 6a is selectively removed by anisotropic etching, such as dry etching, such that the conductor 6a remains only in the gate groove 4, thereby forming the gate line 6, as shown in FIGS. 18A to 18C.

Then, the hard mask 10, the gate insulating film 5 become contact with the hard mask 10, and the oxide film 10a is removed. An upper contact 16 is formed on the exposed semiconductor pillar 2. Then, the cylinder 15 is formed on the upper contact 16. The DRAM shown in FIGS. 1 through 4 is obtained by the above-mentioned processes.

In the DRAM according to this embodiment, the gate lines 6 are provided in the gate grooves 4 that are continuously provided in the side wall 2c of the semiconductor pillar 2 and the side wall 3c of the insulator pillar 3 in the first direction. Therefore, portions of the semiconductor pillar 2 and the insulator pillar 3 overlap the gate lines 6 in a plan view. It is possible to reduce the gap between the semiconductor pillars 2, as compared to the structure in which the gate line is provided between the semiconductor pillars. It is possible to effectively correspond to a reduction in the size of a semiconductor device. In the DRAM according to this embodiment, it is possible to reduce the gap between the semiconductor pillars 2. It is easy to ensure the area of an upper part of the semiconductor pillar 2 and thus ensure the area of the upper contact 16.

In the DRAM according to this embodiment, since the gate line 6 also serves as a word line, it is not necessary to form the word line between the semiconductor pillars 2 and it is possible to reduce the size of a semiconductor device, as compared to the structure in which the word line is formed between the semiconductor pillars 2. In addition, it is easy to manufacture a semiconductor device, as compared to the structure in which the gate lines and the word lines are separately formed.

In the DRAM according to this embodiment, the isolation groove 7 extending in the second direction is provided between the base portions 2b of the semiconductor pillars 2 adjacent to each other in the first direction. The bit line 9 is provided in the bit line groove 8 that is continuously provided in the side wall 7a of the isolation groove 7. Therefore, a portion of the semiconductor pillar 2 overlaps the bit line 9 in a plan view. As a result, it is possible to reduce the gap between the semiconductor pillars 2, as compared to the structure in which the bit line is provided between the semiconductor pillars, and thus effectively correspond to a reduction in the size of a semiconductor device.

The method of manufacturing the DRAM according to this embodiment includes the following processes. A columnar portion forming process is to form, on the silicon substrate 1, a plurality of semiconductor pillars 2 and the insulator pillars 3. The insulator pillars 3 each include the columnar portion 3a and the base portion 3b. The columnar portion 3a is provided between the semiconductor pillars 2 on the silicon substrate 1 in the first direction. The base portion 3b is provided in the silicon substrate 1 at a predetermined depth and extends in the second direction perpendicular to the first direction. As a result, a plurality of pillar columns 11 is formed, which each include the semiconductor pillars 2 and the insulator pillars 3. Each pillar column 11 extends in the first direction and the groove portions 12 that are provided between the pillar columns 11. The groove portions 12 include bottoms 12a through which the silicon substrate 1 and the base portions 3b of the insulator pillars 3 are exposed. Another process is to form the side wall 12b on the side wall of the groove portion 12. An etching process is to perform isotropic etching on the bottom 12a of the groove portion 12 using the side wall 12b as a mask to continuously form the gate grooves 4 in the side wall 2c of the semiconductor pillar 2 and the side wall 3c of the insulator pillar 3. A process is to remove the side wall 12b. A process is to form the gate insulating film 5 on the inner wall of the gate groove 4 of the semiconductor pillar 2. A gate line forming process is to provide the gate line 6 in the gate groove 4. Therefore, it is possible to form the gate line 6 that is electrically isolated from the gate lines of other transistors adjacent to the gate line 6 in the second direction. The gate line 6 is formed using a simple and easy etching process. The gate line 6 is formed without using the difference in the width of the groove between the semiconductor pillars 2. The gate line 6 is formed without forming the side wall for isolating the gate electrode in the groove. As a result, it is possible to easily obtain the DRAM according to this embodiment capable of corresponding to a reduction in the size of a semiconductor device.

### Second Embodiment

In the first embodiment, the DRAM including the transistor with the double gate structure in which the region of the semiconductor pillar 2 interposed between the gate lines 6 serves as a channel of the transistor has been described as an example. However, the semiconductor device according to the present invention is not limited to the DRAM including the transistor with the double gate structure. For example, the present invention may be applied to a DRAM including a transistor with a surround gate structure shown in FIG. 19.

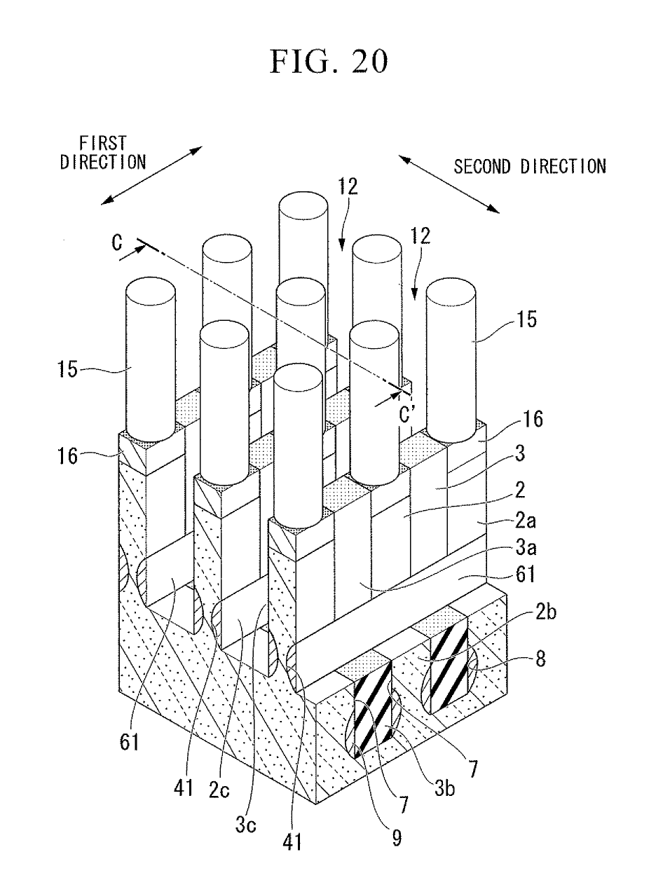

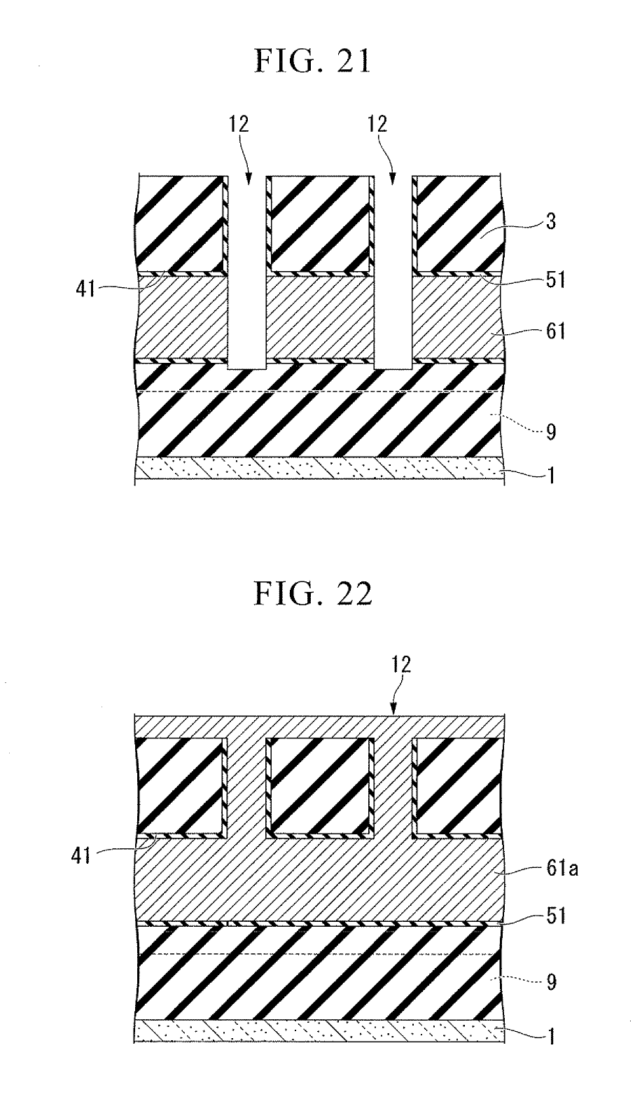

FIG. 19 is a plan view schematically illustrating the planar structure of a portion of a DRAM, in accordance with a second embodiment of the present invention. FIG. 20 is a perspective view illustrating the DRAM shown in FIG. 19. FIG. 21 is a cross-sectional view illustrating the DRAM shown in FIGS. 19 and 20 taken along the line C-C′ of FIGS. 19 and 20.

In the DRAM shown in FIG. 19, the same members as those in the DRAM shown in FIGS. 1 to 4 are denoted by the same reference numerals and a description thereof will be omitted.

Similar to the DRAM shown in FIGS. 1 to 4, the DRAM shown in FIG. 19 includes a plurality of semiconductor pillars 2 that is arranged in a matrix on a silicon substrate 1 in the first direction and the second direction and has a rectangular shape in a plan view and the insulator pillars 3 that are provided between the semiconductor pillars 2 on the silicon substrate 1 in the first direction.

In the DRAM shown in FIG. 19, gate lines 61 are formed so as to extend to a peripheral circuit, and the gate lines 61 also serve as the word lines.

As shown in FIG. 20, the DRAM according to this embodiment includes gate grooves 41 that are continuously provided in the side wall 2c of the semiconductor pillar 2 and the side wall 3c of the insulator pillar 3 in the first direction. The gate grooves 41 are formed in the entire side wall of the semiconductor pillar 2 and the insulator pillar 3 in the first direction. The gate groove 41 of the semiconductor pillar 2 does not pass through the semiconductor pillar 2, but only the gate groove 41 of the insulator pillar 3 passes through the insulator pillar 3. Therefore, as shown in FIG. 20, the gate groove 41 of the semiconductor pillar 2 has an arc shape in a cross-sectional view, similar to the DRAM shown in FIG. 19. However, as shown in FIG. 21, unlike the DRAM shown in FIG. 19, the gate groove 41 of the insulator pillar 3 has a rectangular shape in a cross-sectional view in the second direction, and the gate grooves 41 opposite to each other with the insulator pillar 3 interposed therebetween are integrated with each other.

As shown in FIG. 21, a gate insulating film 51 (not shown in FIG. 20) is provided on the inner wall of the gate groove 41 and the gate line 61 is provided in the gate groove 41. In the DRAM according to this embodiment, the gate lines 61 are arranged so as to surround the semiconductor pillar 2 with the gate insulating film 51 interposed therebetween, and a region surrounded by the gate lines 61 of the semiconductor pillar 2 serves as a channel of the transistor. Therefore, the DRAM according to this embodiment includes a transistor with a vertical surround gate structure.

In the DRAM shown in FIG. 19, a portion of the semiconductor pillar 2 and the entire insulator pillar 3 overlap the gate lines 61 in a plan view, and a portion of the semiconductor pillar 2 overlaps the bit line 9 in a plan view.

### Manufacturing Method:

A method of manufacturing the DRAM shown in FIG. 19 will be described. FIG. 22 is a cross-sectional view illustrating a method of manufacturing the DRAM shown in FIGS. 19 to 21 taken along the line C-C′ of FIGS. 19 and 20.

In the method of manufacturing the DRAM shown in FIG. 19, the processes up to the columnar portion forming process are performed in the same way as those in the method of manufacturing the DRAM shown in FIGS. 1 to 4.

Then, the side wall 12b is formed on the side wall of the groove portion 12 in the same way as in the method of manufacturing the DRAM shown in FIGS. 1 to 4. Then, isotropic etching is performed on the bottom 12a of the groove portion 12 using the side wall 12b as a mask (see FIGS. 15A to 15C) to continuously form the gate grooves 41 in the side wall 2c of the semiconductor pillar 2 and the side wall 3c of the insulator pillar 3, as shown in FIG. 22 (etching process).

In this embodiment, as shown in FIGS. 19 and 22, unlike the method of manufacturing the DRAM shown in FIGS. 1 to 4, the etching process is performed such that the gate groove 41 does not pass through the semiconductor pillar 2 but passes through only the insulator pillar 3. In this way, the gate groove 41 is formed so as to surround the semiconductor pillar 2.

Specifically, the etching process is performed in the same way as in the method of manufacturing the DRAM shown in FIGS. 1 to 4 to form grooves, which will be the gate grooves, such that they interpose the semiconductor pillar 2 (see FIGS. 16A to 16C). Then, only the insulator pillars 3 are etched to form the gate grooves 41 so as to surround the semiconductor pillar 2.

In the etching process, it is preferable that isotropic etching be performed such that the etching rate of the silicon substrate 1 is lower than that of the insulator pillar 3. It is possible to form the gate grooves 41 so as to surround the semiconductor pillar 2 by adjusting the etching rate in the etching process.

Then, the side wall 12b is removed in the same way as that in the method of manufacturing the DRAM shown in FIGS. 1 to 4 and the gate insulating film 51 is formed on the inner walls of the gate grooves 41 of the semiconductor pillar 2 and the insulator pillar 3, as shown in FIG. 22. Then, the gate line 61 is provided in the gate groove 41 in the same way as that in the method of manufacturing the DRAM shown in FIGS. 1 to 4 (gate line (wiring layer) forming process).

That is, as shown in FIG. 22, in the gate line forming process, a conductor 61a which will be the gate line 61 is provided in the groove portion 12. Then, a portion of the conductor 61a is selectively removed by anisotropic etching, such as dry etching, such that the conductor 6a remains only in the gate groove 41, thereby forming the gate line 61, as shown in FIGS. 19 and 21.

Then, the hard mask 10, the gate insulating film 51 coming into contact with the hard mask 10, and the exposed oxide film 10a are removed in the same way as that in the method of manufacturing the DRAM shown in FIGS. 1 to 4, and the upper contact 16 is formed on the exposed semiconductor pillar 2. Then, the cylinder 15 is formed on the upper contact 16. The DRAM shown in FIGS. 19 to 21 is obtained by the above-mentioned processes.

In the DRAM according to this embodiment, the gate lines 61 are provided in the gate grooves 41 that are continuously provided in the side wall 2c of the semiconductor pillar 2 and the side wall 3c of the insulator pillar 3 in the first direction. Therefore, a portion of the semiconductor pillar 2 and the entire insulator pillar 3 overlap the gate line 61 in a plan view. As a result, it is possible to reduce the gap between the semiconductor pillars 2, as compared to the structure in which the gate line is provided between the semiconductor pillars, and thus effectively correspond to a reduction in the size of a semiconductor device. In the DRAM according to this embodiment, it is possible to reduce the gap between the semiconductor pillars 2, similar to the DRAM shown in FIGS. 1 to 4. Therefore, it is easy to ensure the area of an upper part of the semiconductor pillar 2 and thus ensure the area of the upper contact 16.

In the DRAM according to this embodiment, since the gate line 6 also serves as a word line, it is not necessary to form the word line between the semiconductor pillars 2 and it is possible to reduce the size of a semiconductor device, as compared to the structure in which the word line is formed between the semiconductor pillars 2. In addition, it is easy to manufacture a semiconductor device, as compared to the structure in which the gate lines and the word lines are separately formed.

Similar to the method of manufacturing the DRAM shown in FIGS. 1 to 4, the method of manufacturing the DRAM according to this embodiment includes the following processes. A columnar portion forming process is to form the side wall 12b on the side wall of the groove portion 12. An etching process is to perform isotropic etching on the bottom 12a of the groove portion 12 using the side wall 12b as a mask to continuously form the gate grooves 41 in the side wall 2c of the semiconductor pillar 2 and the side wall 3c of the insulator pillar 3. A further process is to remove the side wall 12b. Another process is to form the gate insulating film 51 on the inner wall of the gate groove 41 of the semiconductor pillar 2. A gate line forming process is to provide the gate line 61 in the gate groove 41. Therefore, it is possible to form the gate line 61 that is electrically isolated from the gate lines of other transistors adjacent to the gate line 61 in the second direction. The gate line 61 is formed using a simple and easy etching process. The gate line 61 is formed without using the difference in the width of the groove between the semiconductor pillars 2. The gate line 61 is formed without forming the side wall for isolating the gate electrode in the groove. As a result, it is possible to easily obtain the DRAM according to this embodiment capable of corresponding to a reduction in the size of a semiconductor device.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor substrate;
a first pillar alignment over the substrate, the first pillar alignment comprising first and second semiconductor pillars and a first insulating pillar, the first insulating pillar being disposed between the first and second semiconductor pillars, the first pillar alignment being directed in a first direction, the first pillar alignment having a first side surface having a first groove, the first groove extending in the first direction;
a first insulating film covering at least part of an inside wall of the first groove; and
a first wiring layer in the first groove, the first wiring layer extending in the first direction, the first wiring layer being separated by the first insulating film from the first and second semiconductor pillars.

2. The semiconductor device according to claim 1, wherein the first pillar alignment has a second side surface having a second groove, the second groove extends in the first direction, and the second side surface is opposite to the first side surface,
the semiconductor device further comprises:
a second insulating film covering at least part of an inside wall of the second groove; and
a second wiring layer in the second groove, the second wiring layer extending in the first direction, the second wiring layer being separated by the second insulating film from the first and second semiconductor pillars.

3. The semiconductor device according to claim 2, wherein the first and second grooves are separated by each of the first and second semiconductor pillars, and the first and second grooves are connected with each other at the first insulating pillar,
the first and second wiring layers surround each of the first and second semiconductor pillars.

4. The semiconductor device according to claim 1, further comprising:
a second pillar alignment over the substrate, the second pillar alignment being distanced from the first pillar alignment in a second direction perpendicular to the first direction, the second pillar alignment comprising third and fourth semiconductor pillars and a second insulating pillar, the second insulating pillar being disposed between the third and fourth semiconductor pillars, the second pillar alignment being directed in the first direction, the second pillar alignment having a third side surface having a third groove, the second groove extending in the first direction;
a third insulating film covering at least part of an inside wall of the third groove; and
a third wiring layer in the third groove, the third wiring layer extending in the first direction, the third wiring layer being separated by the third insulating film from the third and fourth semiconductor pillars.

5. The semiconductor device according to claim 4, wherein the first, second, third and fourth semiconductor pillars are arranged in matrix.

6. The semiconductor device according to claim 4, wherein the second pillar alignment has a fourth side surface having a fourth groove, the fourth groove extending in the first direction, and the fourth side surface being opposite to the third side surface,
the semiconductor device further comprises:
a fourth insulating film covering at least part of an inside wall of the fourth groove; and
a fourth wiring layer in the fourth groove, the fourth wiring layer extending in the first direction, the fourth wiring layer being separated by the fourth insulating film from the third and fourth semiconductor pillars.

7. The semiconductor device according to claim 6, wherein the third and fourth grooves are separated by each of the third and fourth semiconductor pillars, and the third and fourth grooves are connected with each other at the second insulating pillar,
the third and fourth wiring layers surround each of the third and fourth semiconductor pillars.

8. The semiconductor device according to claim 1, wherein the semiconductor substrate has a fifth groove, the fifth groove being positioned under the first insulating pillar between the first and second semiconductor pillars, the fifth groove extending in a second direction parallel to the surface of the semiconductor substrate, the second direction being perpendicular to the first direction, the fifth groove having side walls which have sixth and seventh grooves, the sixth and seventh grooves extend in the second direction,
the semiconductor device further comprises:
fifth and sixth wiring layers in the sixth and seventh grooves, respectively, and the fifth and sixth wiring layers extending in the second direction.

9. The semiconductor device according to claim 8, wherein the sixth and seventh grooves are positioned at lower portions of the side walls of the fifth groove.

10. The semiconductor device according to claim 8, wherein the fifth groove is filled with an insulating material.

11. The semiconductor device according to claim 8, wherein the fifth and sixth wiring layers are bit lines.

12. The semiconductor device according to claim 1, wherein the first wiring layer is a word line.

13. The semiconductor device according to claim 1, wherein the first side surface of the first pillar alignment is a continuing flat side surface and the first groove continuously extends in the first direction.

14. The semiconductor device according to claim 1, wherein the first groove is positioned at a lower portion of the first pillar alignment.

15. A semiconductor device comprising:
a substrate;
first and second semiconductor pillars over the substrate, the first and second semiconductor pillars being aligned in a first direction, the first and second semiconductor pillars having first and second grooves extending in the first direction;
a first insulating pillar between the first and second semiconductor pillars, the first insulating pillar eclectically isolating the first and second semiconductor pillars from each other, the first insulating pillar having a third groove extending in the first direction, the first, third and second grooves forming a first continuing groove extending in the first direction;
a first insulating film covering at least the first and second grooves; and
a first wiring layer extending in the first continuing groove, the first wiring layer extending in the first direction, the first wiring layer being separated by the first insulating film from the first and second semiconductor pillars.

16. The semiconductor device according to claim 15, wherein the first and second semiconductor pillars have fourth and fifth grooves extending in the first direction, the fourth and fifth grooves being positioned in opposite side to the first and second grooves;
the first insulating pillar has a sixth groove extending in the first direction, the fourth, sixth and fifth grooves forming a second continuing groove extending in the first direction;
a second insulating film covering at least the fourth and fifth grooves; and
a second wiring layer extending in the second continuing groove, the second wiring layer extending in the first direction, the second wiring layer being separated by the second insulating film from the first and second semiconductor pillars.

17. The semiconductor device according to claim 15, further comprising:
third and fourth semiconductor pillars over the substrate, the third and fourth semiconductor pillars being aligned in the first direction, the third and fourth semiconductor pillars being distanced from the first and second semiconductor pillars, the third and fourth semiconductor pillars having seventh and eighth grooves extending in the first direction;
a second insulating pillar between the third and fourth semiconductor pillars, the second insulating pillar eclectically isolating the third and fourth semiconductor pillars from each other, the second insulating pillar having a ninth groove extending in the first direction, the seventh, ninth and eighth grooves forming a third continuing groove extending in the first direction;
a third insulating film covering at least the seventh and eighth grooves; and
a third wiring layer extending in the third continuing groove, the third wiring layer extending in the first direction, the third wiring layer being separated by the third insulating film from the third and fourth semiconductor pillars.

18. A semiconductor device comprising:
a substrate;
first and second semiconductor pillars over the substrate, the first and second semiconductor pillars being aligned in a first direction;
a first insulator eclectically isolating the first and second semiconductor pillars from each other; and
a first wiring layer continuously extending inside a first continuing groove that extends through the first and second semiconductor pillars and the first insulator, the first continuing groove extending in a first direction along which the first and second semiconductor pillars are aligned.

19. The semiconductor device according to claim 18, wherein the semiconductor substrate has a second continuing groove that extends in a second direction perpendicular to the first direction, the second continuing groove being positioned under the first insulator between the first and second semiconductor pillars, the second continuing groove having side walls which have third and fourth grooves, the third and fourth grooves extend in the second direction,
the semiconductor device further comprises:
second and third wiring layers in the third and fourth grooves, respectively, and the second and third wiring layers extending in the second direction.

20. The semiconductor device according to claim 19, wherein the first wiring layer is a word line, and the second and third wiring layers are bit lines.
